(19) United States
(12) Patent Application Publication
(10) Pub. No.: US 2012/0326794 A1
(43) Pub. Date: Dec. 27, 2012

(54) DIGITAL AMPLITUDE CONTROL CIRCUITRY FOR CRYSTAL OSCILLATOR CIRCUITRY AND RELATED METHODS

(76) Inventor: Abhishek V. Kammula, Austin, TX (US)

(21) Appl. No.: 13/169,689

(22) Filed: Jun. 27, 2011

(51) Int. Cl. H03B 1/00

(52) U.S. Cl. 331/15

(57) ABSTRACT

Methods and systems are disclosed that utilize digital control loops to control an amplitude level for output signals generated by crystal oscillator circuitry. The disclosed embodiments utilize multiple selectable current drive circuits to control the amplitude level of the output signals from crystal oscillator circuitry. The current drive circuits are selectably used, or not used, to provide a bias current to the crystal oscillator circuitry based upon a multi-bit digital control signal. The multi-bit digital control signal can be generated, for example, by control circuitry that compares the oscillator output signal to a reference output signal level.

### TECHNICAL FIELD OF THE INVENTION

This invention relates to crystal oscillator circuitry and, more particularly, to controlling an output amplitude level for oscillator output signals generated by crystal oscillator circuitry.

### BACKGROUND

Many integrated circuits exist that utilize signals generated by crystal-based oscillators. Crystal oscillator output signals are used, for example, as reference signals for the generation of clock signals, timing signals and/or other desired signals. For some implementations, there is need to control the output amplitude level of oscillator output signals. In part, controlling this output amplitude level can be desirable because non-linear effects and jitter can be introduced in the crystal oscillator output signals if the amplitude is too high. Further, controlling this output amplitude level can also be desirable because overdriving the crystal can increase the rate of aging for the crystal, thereby shortening its lifetime.

FIG. 1A (Prior Art) is a block diagram of an embodiment 100 for a prior solution for controlling an output amplitude level for crystal oscillator circuitry using an analog control loop. Crystal oscillator circuitry 102 is coupled to receive a variable bias current from current source circuitry 105. This variable bias current controls the amplitude level for the oscillator output signal (OSC) 107, and this variable bias current is varied based upon an analog voltage control signal (V_{CTRL}) 106. The analog voltage control signal (V_{CTRL}) 106 is generated by amplitude detector and analog control circuitry 130. The amplitude detector and analog control circuitry 130 receives the oscillator output signal (OSC) 107, detects its amplitude level, and generates the analog voltage control signal (V_{CTRL}) 106 that controls the output amplitude level of the oscillator output signal (OSC) 107 by adjusting the bias current supplied to the crystal oscillator circuitry 102 through the current source circuitry 105.

FIG. 1B (Prior Art) is a more detailed diagram of an embodiment 150 that utilizes an analog control loop to control the output amplitude level for crystal oscillator circuitry 102. As depicted, the crystal oscillator circuitry 102 includes a crystal 124 and a resistor 122 coupled between node 126 and node 128. Nodes 126 and 128 are also coupled to transistor 120, which can be an NMOS transistor, if desired. In particular, node 126 is coupled to the drain of transistor 120, and node 128 is coupled to the gate of transistor 120. The source of transistor 120 is coupled to ground. A bias current from a supply voltage (V_{DD}) is provided to node 126 within the crystal oscillator circuitry 102 through current source circuitry 105. Current source circuitry 105 can be implemented, for example, using a current drive transistor 104, such as a PMOS transistor, if desired. For the embodiment depicted, the source of transistor 104 is coupled to the supply voltage (V_{DD}). The drain of transistor 104 is coupled to the crystal oscillator circuitry 102. And the gate of transistor 104 is coupled to a analog voltage control signal (V_{CTRL}) 106.

In operation, the crystal oscillator circuitry 102 resonates based upon the oscillations provided by the crystal 124 and produces an oscillator output signal (OSC) 107. This oscillator output signal (OSC) 107 can be used by other circuitry, for example, to generate clock, timing and/or other desired signals. The amplitude level of the oscillator output signal (OSC) 107 is controlled by the bias current provided from the current source circuitry 105. And the bias current from the current source circuitry 105 is controlled by the analog voltage control signal (V_{CTRL}) 106 that is applied to the gate of transistor 104. Thus, the output amplitude level of the oscillator output signal (OSC) 107 is controlled by the analog voltage control signal (V_{CTRL}) 106.

The voltage control signal (V_{CTRL}) 106 is determined by the analog control loop that includes amplitude detector and analog control circuitry 130. In the embodiment 150, the amplitude detector and analog control circuitry 130 includes peak detector 108 and an error amplifier 110. The peak detector operates to determine the peak amplitude level of the oscillator output signal (OSC) 107. The output of the peak detector 108 is then provided to error amplifier 110 where it is compared to a threshold voltage (Vth) 112 to determine an amplitude error value. The error amplifier 110 then outputs the analog voltage control signal (V_{CTRL}) 106 as an amplified version of the error value. In operation, the analog control loop continually attempts to keep the output of the peak detector 108 equal to the threshold voltage (Vth) 112 by adjusting the analog voltage control signal (V_{CTRL}) 106 applied to the transistor 104. The analog control loop thereby attempts to produce a well-defined amplitude for the oscillator output signal (OSC) 107 that is maintained during operation despite power supply, voltage and/or temperature variations of the circuitry associated with the crystal oscillator circuitry 102.

This use of an analog control loop to control the amplitude of the crystal oscillator circuitry, however, has disadvantages. For example, performance issues can arise in the analog control loop where the threshold voltage (Vth) 112 has a spur, as such a spur will tend to show up in the oscillator output signal (OSC) 107 as an undesirable modulation in the output amplitude level. In addition, noise associated with the error amplifier 110 also leads to undesirable phase noise in the oscillator output signal (OSC) 107. Due to such issues, therefore, in order to achieve a relatively low-noise and spur-free analog voltage control signal (V_{CTRL}) 106 for the analog control loop, the threshold voltage (Vth) 112 must be generated using circuitry having a very high PSRR (power supply rejection ratio), and the error amplifier 110 must have very low noise. Both of these requirements lead to complex, high-power and large-size circuit implementations.

### SUMMARY OF THE INVENTION

Methods and systems are disclosed that utilize digital control loops to control an amplitude level for output signals generated by crystal oscillator circuitry. The disclosed embodiments utilize multiple selectable current drive circuits to control the amplitude level of the output signals form the crystal oscillator circuitry. The current drive circuits are selectably used, or not used, to provide a bias current to the crystal oscillator circuitry based upon a multi-bit digital control signal. The multi-bit digital control signal can be generated, for example, by control circuitry that compares the oscillator output signal to a reference output signal level. Other features and variations can also be implemented, as desired, and related systems and methods can be utilized, as well.

In one embodiment, digital crystal oscillator amplitude control circuitry is disclosed that includes bias current circuitry, amplitude detection circuitry, control circuitry and a plurality of selectable current drive circuits. The bias current circuitry is configured to provide a variable bias current to crystal oscillator circuitry to control an amplitude level for an output signal from the crystal oscillator circuitry. The plurality of selectable current drive circuits are located within the bias current circuitry, and each of the plurality of selectable current drive circuits is controlled by at least one bit of a multi-bit digital control signal. The amplitude detection circuitry is configured to receive an output signal from the crystal oscillator circuitry and to generate an amplitude level indicator signal. And the control circuitry is coupled to the bias current circuitry and configured to provide the multi-bit digital control signal to the plurality of selectable current drive circuits based upon the amplitude level indicator signal.

In a further embodiment, each of the plurality of selectable current drive circuits includes a current drive transistor coupled to a switch circuit controlled by at least one bit of the multi-bit digital control signal. In a still further embodiment, each current drive transistor has its source and drain coupled between a supply node and a common output node; each switch circuit is configured to selectably pass a voltage control signal to a gate of a current drive transistor; and the common output node is coupled to provide the variable bias current to the crystal oscillator circuitry. In another embodiment, each current drive transistor has its source and drain coupled between a supply node and a switch circuit; a voltage control signal is coupled to a gate of each drive transistor; each switch circuit is configured to selectably couple the current drive transistor to a common output node; and the common output node is coupled to provide the variable bias current to the crystal oscillator circuitry. Still further, the amplitude control circuitry can include a peak detector and a comparator.

In another embodiment, the control circuitry includes clock generation circuitry coupled to receive the output signal from the crystal oscillator circuitry and to generate one or more clock signals. Further, the control circuitry can include logic circuitry configured to receive the amplitude level indicator signal, to receive the one or more clock signals from the clock generation circuitry, and to output the multi-bit digital control signal. Still further, the logic circuitry can be a finite state machine.

In a further embodiment, the plurality of selectable current drive circuits can have a same weight. In another further embodiment, at least two of the plurality of selectable current drive circuits have different weights. Further, the control circuitry can be configured to set the multi-bit digital control signal to provide initially a maximum amplitude level for the output signal from the crystal oscillator circuitry.

In one embodiment, a method for digitally controlling an amplitude level of an output signal from crystal oscillator circuitry is disclosed that includes determining an amplitude level for an output signal from crystal oscillator circuitry, generating a multi-bit digital control signal based upon the amplitude level, applying the multi-bit digital control signal to a plurality of selectable current drive circuits to provide a variable bias current to the crystal oscillator circuitry, and repeating the determining, generating and applying steps to control the amplitude level of the output signal from the crystal oscillator circuitry.

In an additional embodiment, each of the plurality of selectable current drive circuits can include a current drive transistor coupled to a switch circuit, and the applying step can include applying at least one bit of the multi-bit digital control signal to each switch circuit. Still further, the method can include utilizing the multi-bit digital control signal to selectably apply a voltage control signal to a gate of each current drive transistor to determine which of the plurality of selectable current drive circuits provide a current to a common output node and utilizing the common output node to provide the variable bias current to the crystal oscillator circuitry. In another embodiment, the method can include utilizing the multi-bit digital control signal to selectably couple each drive transistor to a common output node and utilizing the common output node to provide the variable bias current to the crystal oscillator circuitry.

In a further embodiment, the method can include generating one or more clock signals based upon the output signal from the crystal oscillator circuitry. Still further, the method can include using logic circuitry to generate the multi-bit digital control signal based upon the amplitude level and using the one or more clock signals to control the logic circuitry. In addition, the method can include setting the multi-bit digital control signal to provide initially a maximum amplitude level for the output signal from the crystal oscillator circuitry.

Other features and variations can also be implemented, as desired, and related systems and methods can be utilized, as well.

### DESCRIPTION OF THE DRAWINGS

It is noted that the appended drawings illustrate only example embodiments of the invention and are, therefore, not to be considered limiting of its scope, for the invention may admit to other equally effective embodiments.

FIG. 1A (Prior Art) is a block diagram of an embodiment for amplitude control circuitry for crystal oscillator circuitry that uses an analog control loop.

FIG. 1B (Prior Art) is a more detailed diagram of an embodiment for amplitude control circuitry for crystal oscillator circuitry that uses an analog control loop.

FIG. 2A is a block diagram of an embodiment for digital amplitude control circuitry for crystal oscillator circuitry that utilizes a digital control loop.

FIG. 2B is a more detailed diagram of an embodiment for digital amplitude control circuitry for crystal oscillator circuitry that utilizes a digital control loop.

FIG. 3 is a detailed diagram of an alternative embodiment for digital amplitude control circuitry for crystal oscillator circuitry that utilizes a digital control loop.

FIG. 4 is a block diagram of an embodiment for control circuitry that can be use with the embodiment of FIG. 3.

FIG. 5 is a process flow diagram of an embodiment for digital control of an output amplitude for crystal oscillator circuitry.

### DETAILED DESCRIPTION OF THE INVENTION

Methods and systems are disclosed that utilize digital control loops to control an amplitude level for oscillator output signals generated by crystal oscillator circuitry. The disclosed embodiments utilize multiple selectable current drive circuits to control the amplitude level for the output signal from the crystal oscillator circuitry. The current drive circuits are selectably used, or not used, to provide a bias current to the crystal oscillator circuitry based upon a multi-bit digital control signal. The multi-bit digital control signal can be generated, for example, by control circuitry that compares the oscillator output signal to a reference output signal level. This comparison is used to adjust the bias current for the crystal oscillator circuitry through adjustments to the multiple-bit digital control signal. Other features and variations can also be implemented, as desired, and related systems and methods can be utilized, as well.

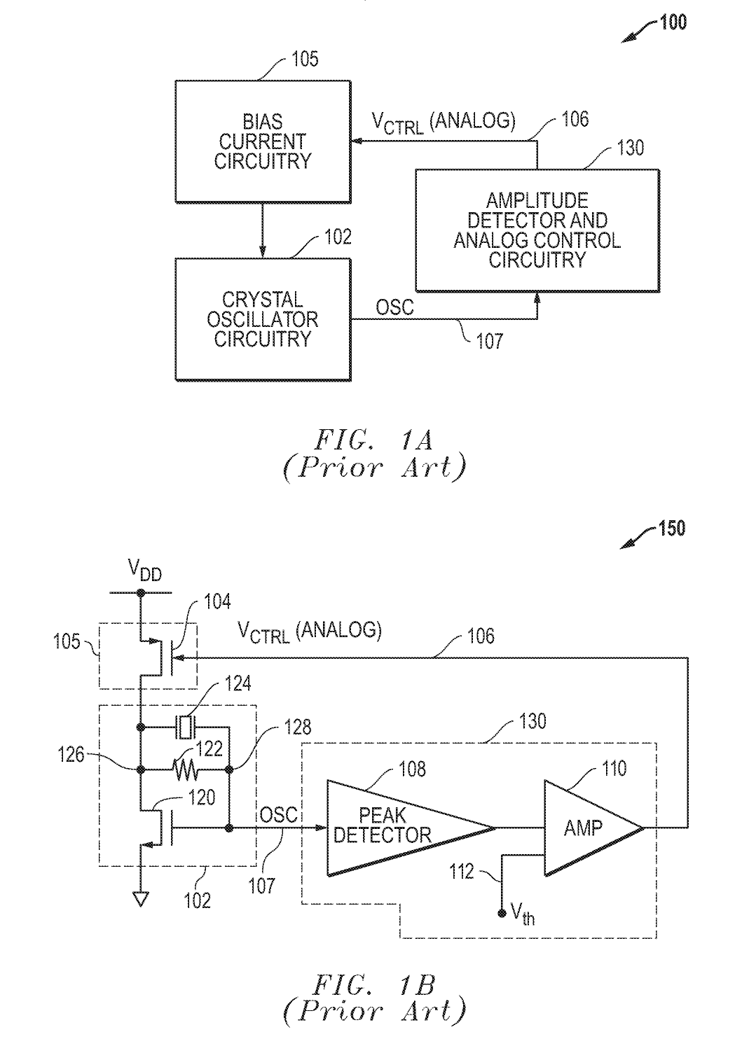

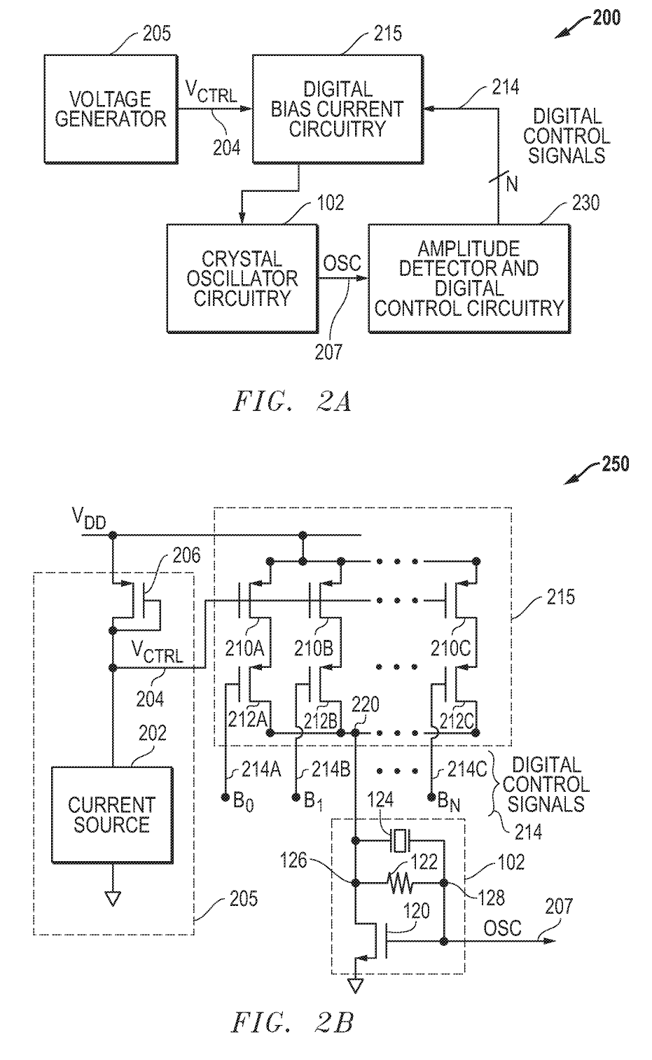

FIG. 2A is a block diagram of an embodiment 200 for digital crystal oscillator amplitude control circuitry. As with FIG. 1A (Prior Art), crystal oscillator circuitry 102 is coupled to receive a variable bias current from. However, unlike embodiment 100, embodiment 200 utilizes a digital control loop to determine the amount of bias current provided to the crystal oscillator circuitry 102 to control the amplitude level for the oscillator output signal (OSC) 207. For embodiment 200, for example, the variable bias current is varied based upon a multi-bit (N-bit) digital control signal 214 that is applied to digital bias current circuitry 215 to adjust the bias current provided to the crystal oscillator circuitry 102, thereby controlling the amplitude level for the oscillator output signal (OSC) 207. The digital bias current circuitry 215 also receives the analog voltage control signal (V_{CTRL}) 204 from voltage generator 205, and this analog voltage control signal (V_{CTRL}) 204 is used to bias drive circuitry within the digital bias current circuitry 215. The multi-bit (N-bit) digital control signal 214 is generated by the amplitude detector and digital control circuitry 230, which receives the oscillator output signal (OSC) 207, detects its amplitude level as compared to a desired amplitude level, and generates the multi-bit (N-bit) digital control signals 214 to control the output amplitude level of the oscillator output signal (OSC) 207.

FIG. 2B is a more detailed diagram of an embodiment 250 that utilizes a digital control loop to control an amplitude level for the oscillator output signal (OSC) 207 provided by crystal oscillator circuitry 102. As with FIG. 1B (Prior Art), the crystal oscillator circuitry 102 includes a crystal 124 and a resistor 122 coupled between node 126 and node 128. Nodes 126 and 128 are also coupled to transistor 120, which can be a NMOS transistor as shown, if desired. In particular, node 126 is coupled to the drain of transistor 120, and node 128 is coupled to the gate of transistor 120. The source of transistor 120 is coupled to ground. In operation, the crystal oscillator circuitry 102 resonates based upon the oscillations provided by the crystal 124 and produces an oscillator output signal (OSC) 207. It is noted that other configurations for crystal oscillator circuitry 102 could also be utilized that still take advantage of the digital control loops and digitally controlled bias currents described herein.

In contrast with FIG. 1B (Prior Art), embodiment 250 utilizes a plurality of digitally selectable current drive circuits to generate the controlled bias current provided to the crystal oscillator circuitry 102. In particular, for the embodiment depicted, a controlled bias current is provided to the crystal oscillator circuitry 102 using digital control signals 214A, 214B . . . 214C (B₀, B₁ . . . B_{N}) that are applied to digital bias current circuitry 215. The digital bias current circuitry 215 includes a plurality of current drive transistors 210A, 210B . . . 210C connected in parallel that serve as the selectable current drive circuits that provide drive currents to node 220, which in turn serves to provide the controlled bias current to the crystal oscillator circuitry 102. The current drive transistors 210A, 210B . . . 210C are selectively coupled between the supply voltage (V_{DD}) and node 220 using a plurality of digitally controlled transistors 212A, 212B . . . 212C. The transistors 212A, 212B . . . 212C serve as switches that are controlled by the digital control signals 214A, 214B . . . 214C (B₀, B₁ . . . B_{N}) that make up the multi-bit digital control signal 214.

For the embodiment depicted, the gate of each of the transistors 212A, 212B . . . 212C is coupled to receive one of the digital control signals 214A, 214B . . . 214C (B₀, B₁ . . . B_{N}). The drain of each of the transistors 212A, 212B . . . 212C is connected to node 220. The source of each of the transistors 212A, 212B . . . 212C is connected to the drain of one of the current drive transistors 210A, 210B . . . 210C. The source for each of the current drive transistors 210A, 210B . . . 210C is connected to the supply voltage (V_{DD}). And the gates of the current drive transistors 210A, 210B . . . 210C are connected the analog voltage control signal (V_{CTRL}) 204. It is noted that the current drive transistors 210A, 210B . . . 210C and the switch transistors 212A, 212B . . . 212C can be PMOS transistors as shown, if desired. However, these transistors could also be implemented as NMOS transistors, if desired.

The analog voltage control signal (V_{CTRL}) 204 is provided by the voltage generator 205. For the embodiment depicted, the voltage generator 205 includes current source circuitry 202 having an output coupled to the supply voltage (V_{DD}) through a diode-connected transistor 206, which operates as a load circuit. Transistor 206 has its source coupled to the supply voltage (V_{DD}), and its drain and gate nodes connected together to the output of the voltage generator 205. The voltage drop provided by transistor 206 will depend upon the current output of the current source circuitry 202. The current source circuitry 202 is configured to have an output current that is independent of the operating temperature of the circuitry. As such, the analog voltage control signal (V_{CTRL}) 204 will not vary significantly with the operating temperature. As stated above, the analog voltage control signal (V_{CTRL}) 204 is provided as a bias voltage to the gates of the current drive transistors 210A, 210B . . . 210C.

In operation, the amplitude level of the oscillator output signal (OSC) 207 can be detected and then digitally controlled using the digital control signals 214A, 214B . . . 214C (B₀, B₁ . . . B_{N}). This digital control loop provides for advantages in controlling the amplitude level of the oscillator output signal. For example, noise and spurs on the digital control signals 214A, 214B . . . 214C (B₀, B₁ . . . B_{N}) will have reduced impact on the oscillator operation as they are coupled to the gates of transistors 212A, 212B . . . 212C, which can be configured in a cascode arrangement. Further, the analog voltage control signal (V_{CTRL}) is generated separately from the digital control loop, thereby reducing circuit requirements for the current source circuitry to be used, which can be designed to have good supply rejection, if desired. In addition and in contrast with prior solutions, noise and spurs on the threshold voltage (Vth) have reduced or negligible impact on oscillator operation with the described embodiments, as the control signals are now generated as digital signals and not as an amplified error signal based upon the threshold voltage (Vth). Still further, as described in more detail below, the control circuitry for generating the digital control signals can utilize the oscillator output signal to generate its internal clock signals, which allows the crystal oscillator circuitry and the crystal oscillator amplitude control circuitry to be self-contained.

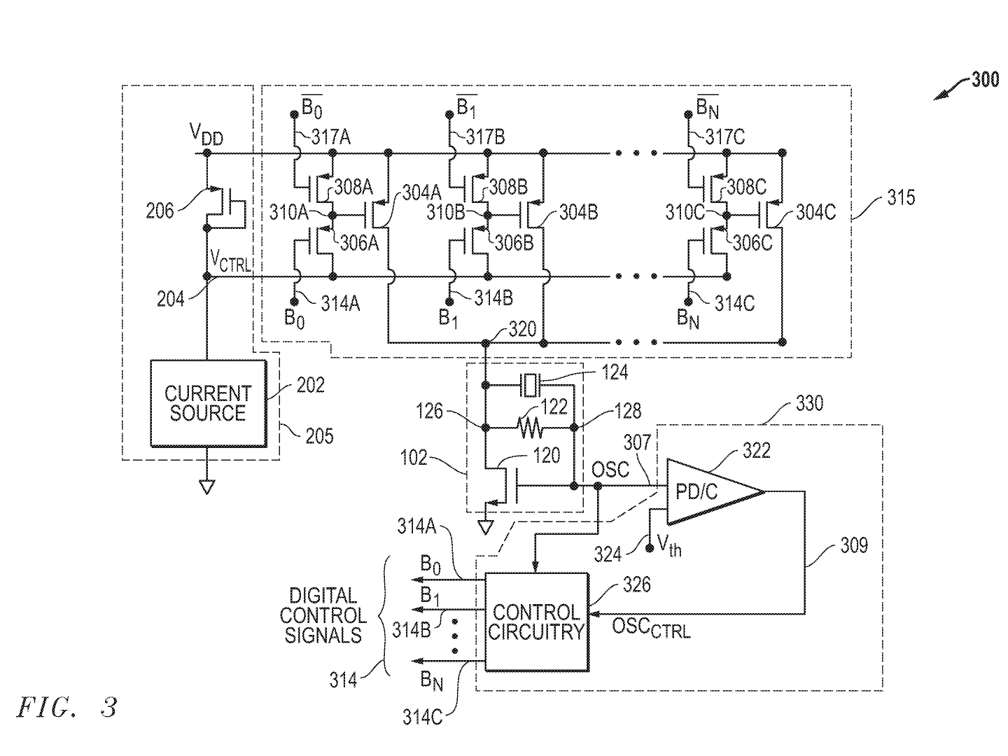

FIG. 3 is a detailed diagram of an embodiment 300 including digital control of an amplitude level for an oscillator output signal (OSC) 207 generated by crystal oscillator circuitry 102. Similar to the embodiment 250 of FIG. 2B, embodiment 300 includes a voltage generator 205 that includes a diode-connected transistor 206 coupled to a current source 202 to provide an analog voltage control signal (V_{CTRL}) 204. Further, as with embodiment 250, a plurality of current drive transistors 304A, 304B . . . 304C within the digital bias current circuitry 315 are coupled in parallel between the supply voltage (V_{DD}) and node 320 to provide a variable drive current to node 320, which is used to provide the bias current to the crystal oscillator circuitry 102. The current drive transistors 304A, 304B . . . 304C operate as the plurality of selectable current drive circuits for the embodiment. The crystal oscillator circuitry 102 again includes crystal 124, resistor 122 and transistor 120 and provides an oscillator output signal (OSC) 307.

In contrast with embodiment 250, however, embodiment 300 applies digital control signals 314A, 314B . . . 314C (B₀, B₁ . . . B_{N}), which make up the multi-bit digital control signal 314, to selectively couple the analog voltage control signal (V_{CTRL}) 204 to the gates of the current drive transistors 304A, 304B . . . 304C through switch transistors 306A, 306B . . . 306C. In particular, one of the digital control signals 314A, 314B . . . 314C (B₀, B₁ . . . B_{N}) is coupled to the gate of each of the switch transistors 306A, 306B . . . 306C to selectively provide the voltage control signal (V_{CTRL}) 204 to the gate nodes 310A, 310B . . . 310C of the current drive transistors 304A, 304B . . . 304C. Also as depicted, inverted digital control signals 317A, 317B . . . 317C (B₀_{_{—}}bar, B₁_{_{—}}bar . . . B_{N}_{_{—}}bar) are used to couple the gate nodes 310A, 310B . . . 310C to the supply voltage (V_{DD}) through switch transistors 308A, 308B . . . 308C in order to keep current drive transistors 304A, 304B . . . 304C turned off when they have not been selected. (The “_bar” suffix is being used to represent a logically inverted signal.)

It is noted that for the embodiment 300 depicted, transistors 308A, 308B . . . 308C can be PMOS transistors as shown, if desired, having their sources coupled to the supply voltage (V_{DD}), their drains coupled to nodes 310A, 310B . . . 310C, and their gates connected to the inverted digital control signals 317A, 317B . . . 317C (B₀_{_{—}}bar, B₁_{_{—}}bar . . . B_{N}_{_{—}}bar). Transistors 306A, 306B . . . 306C can also be PMOS transistors as shown, if desired, having their sources coupled to nodes 310A, 310B . . . 310C, their drains coupled to the voltage control signal (V_{CTRL}) 204, and their gates connected to the digital control signals 314A, 314B . . . 314C (B₀, B₁ . . . B_{N}). Transistors 304A, 304B . . . 304C can also be PMOS transistors, if desired, having their gates coupled to nodes 310A, 310B . . . 310C, their sources coupled to the supply voltage (V_{DD}), and their drains coupled to node 320. It is noted that other circuit configurations as well as NMOS transistors could also be used for the digital bias current circuitry 315, if desired, while still providing a digital control loop and a digitally controlled bias current, as described herein.

As further depicted in the embodiment 300 of FIG. 3, the digital control signals 314A, 314B . . . 314C (B₀, B₁ . . . B_{N}) can be generated using amplitude detector and digital control circuitry 330, which includes peak detector and comparator (PD/C) 322 and control circuitry 326. The oscillator output signal (OSC) 307 is provided to a peak detector and comparator (PD/C) 322 that produces an oscillator control signal (OSC_{CTRL}) 309. The peak detector and comparator (PD/C) 322 determines the peak amplitude for the oscillator output signal (OSC) 307 and compares it to a threshold voltage (Vth) 324. The oscillator control signal (OSC_{CTRL}) 309 represents a digital result of this comparison and operates as a high/low amplitude level indicator signal that is provided to control circuitry 326. Control circuitry 326 utilizes the oscillator control signal (OSC_{CTRL}) 309 to generate the digital control signals 314A, 314B . . . 314C (B₀, B₁ . . . B_{N}) that determine the output amplitude level of the oscillator output signal (OSC) 307. It is also noted that the oscillator output signal (OSC) 307 can also be provided to the control circuitry 326 to be used to generate timing signals for the operation of the control circuitry 326.

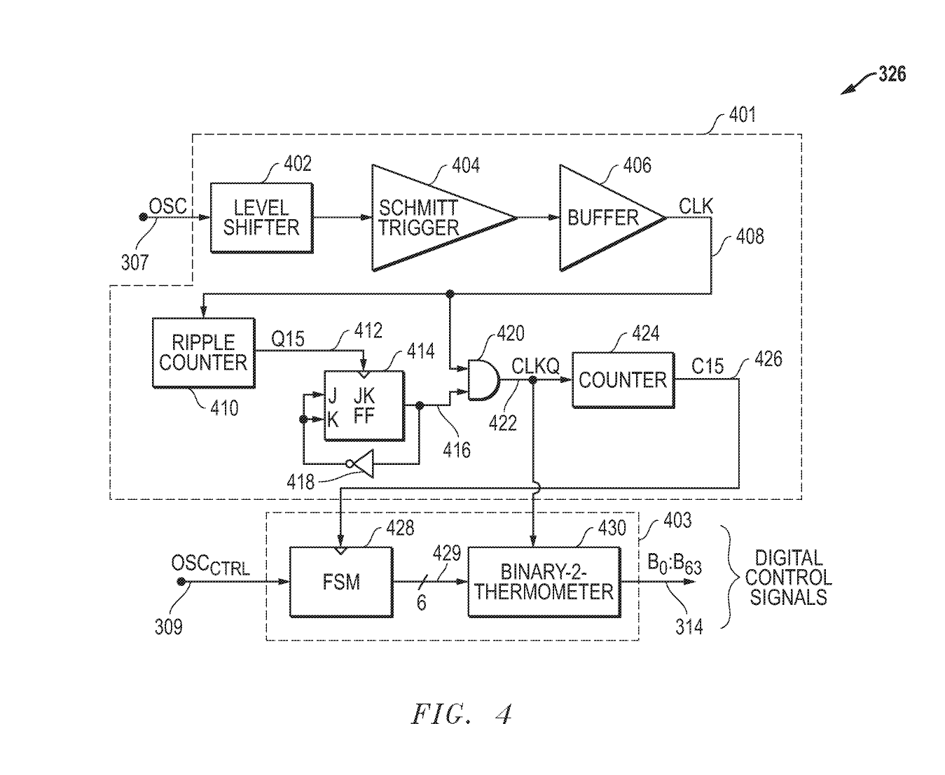

FIG. 4 is a diagram of control circuitry 326 that can be used within the embodiment of FIG. 3. The control circuitry 326 includes clock generation circuitry 401 and logic circuitry 403. The oscillator output signal (OSC) 307 is passed through a level shifter 420 to a Schmitt trigger 404. The output of the Schmitt trigger 404 is passed through a buffer 406 to provide a clock signal (CLK) 408. As depicted, the clock signal (CLK) 408 is used to time a ripple counter 410, which can be for example a 16-bit ripple counter. The most significant bit (MSB) of the ripple counter 410 can be provided as an output (Q15) 412 to be used to trigger transitions in a JK flip-flop (JK FF) 414. The JK flip-flop 414 can provide an output signal 416 to an AND gate 420, which also receives the clock signal (CLK) 408 as an input. The output signal 416 can also be provided to the JK inputs for the JK flip-flop 414 through an inverter 418. The output of the AND gate 420 can be used as a qualified clock signal (CLKQ) 422 that is provided to a counter 424 and as a clock input to binary-2-thermometer circuitry 430. The counter 424 can also be a 16-bit counter, and the MSB of the counter 424 can be provided as an output (C15) 426 to a clock input of a FSM (finite state machine) 428. The FSM 428 receives the oscillator control signal (OSC_{CTRL}) 309 and provides a multi-bit output signal 429, such as for example a 6-bit signal, to the binary-2-thermometer circuitry 430. The binary-2-thermometer circuitry 430 outputs the digital control signals 314, which can be a 64-bit signal (B₀:B₆₃), if desired.

It is noted that the control circuitry 326 depicted in FIG. 4 is one example embodiment, and other embodiments could be utilized, as desired. For example, FSM 428 operates as logic circuitry that receives the oscillator control signal (OSC_{CTRL}) 309 and could be implemented using different logic circuitry embodiments. In operation, the FSM 428 is configured to use the oscillator control signal (OSC_{CTRL}) 309 as an up or down signal level indicator. If the oscillator control signal (OSC_{CTRL}) 309 indicates that the output amplitude of the crystal oscillator signal is higher than the threshold voltage (Vth) 324, then the FSM 428 adjusts the multi-bit digital control signal 314 to decrease the bias current to node 320. If the oscillator control signal (OSC_{CTRL}) 309 indicates that the output amplitude of the crystal oscillator signal is lower than the threshold voltage (Vth) 324, then the FSM 428 adjusts the multi-bit digital control signal 314 to increase the bias current to node 320. Thus, the FSM 428 provides digital control of the amplitude level for the crystal oscillator circuitry 102. It is again noted that this digital control could be implemented in different ways while still taking advantage of the digital crystal oscillator amplitude control described herein.

It is also noted that the digital control signals (e.g., 214A-C, 314A-C) can be initially set to provide a maximum bias current to the crystal oscillator circuitry 102. The bias current can then be stepped down until a desired amplitude level is achieved. Other control implementations could also be used, if desired. For example, the digital control signals (e.g., 214A-C, 314A-C) can be initially set to provide a bias current within a middle point of an adjustable range. The digital control signals (e.g., 214A-C, 314A-C) can then be adjusted up or down depending upon the output signal amplitude level for the crystal oscillator circuitry.

It is further noted that the plurality of current drive circuits, such as transistors (e.g., 210A-C, 304A-C), can be weighted the same, if desired, or can be provided with different weights, if desired. The weighting of current drive transistors, for example, can be determined by the size of the transistors, as the size of the transistors will determine the size of the drive current provided by that transistor to the output node (e.g., node 220, node 320). Thus, a variety of weighting schemes could be implemented, as desired, along with a variety of control algorithms such that the output signal amplitude level of the crystal oscillator circuitry is adjusted based upon which of the plurality of selectable current drive circuits are selected to be active at any given time to provide the bias current to the crystal oscillator circuitry.

In addition, it is noted that unlike the analog control loop, the digital control loop does not have to be kept running once a desired amplitude is achieved. For example, the FSM 428 can be turned off once a desired amplitude has been achieved if variations due to operating temperature are acceptable. Further, if temperature variations are not acceptable, the bias current source generator 202 can be implemented with a compensating temperature coefficient. Further, a separate microcontroller (MCU) or other control circuitry could take over the control of the digital control signals once the integrated circuit has been powered up. One advantage of the FSM 428 is that it can be configured to operate during start-up using the oscillator output signal itself to clock the operations of the FSM 428.

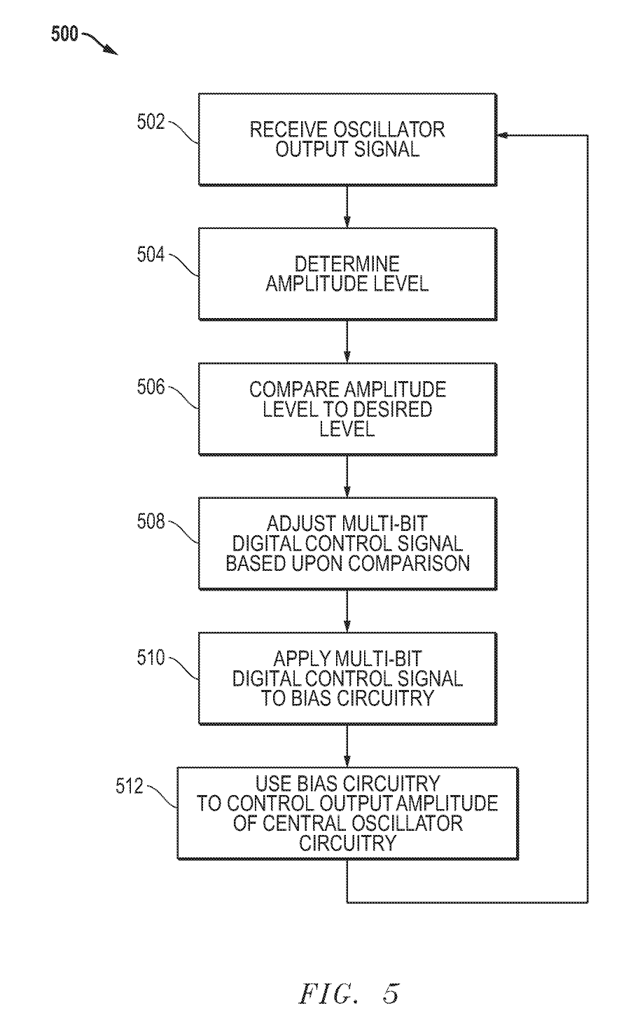

FIG. 5 is a process diagram of an embodiment 500 for digitally controlling an output amplitude of crystal oscillator circuitry using a multi-bit digital control signal. In block 502, the oscillator output signal is received. In block 504, an amplitude level is determined for the oscillator output signal. In block 506, the amplitude level is compared to a desired level for the amplitude of the oscillator output signal. In block 508, the multi-bit digital control signal is adjusted based upon the comparison. In block 510, the multi-bit digital control signal is applied to the bias current circuitry. And in block 512, the bias current circuitry is used to control the output amplitude level of the oscillator output signal generated by the crystal oscillator circuitry.

Further modifications and alternative embodiments of this invention will be apparent to those skilled in the art in view of this description. It will be recognized, therefore, that the present invention is not limited by these example arrangements. Accordingly, this description is to be construed as illustrative only and is for the purpose of teaching those skilled in the art the manner of carrying out the invention. It is to be understood that the forms of the invention herein shown and described are to be taken as the presently preferred embodiments. Various changes may be made in the implementations and architectures. For example, equivalent elements may be substituted for those illustrated and described herein, and certain features of the invention may be utilized independently of the use of other features, all as would be apparent to one skilled in the art after having the benefit of this description of the invention.

What is claimed is:

1. Digital crystal oscillator amplitude control circuitry, comprising:
bias current circuitry configured to provide a variable bias current to crystal oscillator circuitry to control an amplitude level for an output signal from the crystal oscillator circuitry;
a plurality of selectable current drive circuits within the bias current circuitry, each of the plurality of selectable current drive circuits being controlled by at least one bit of a multi-bit digital control signal;
amplitude detection circuitry configured to receive an output signal from the crystal oscillator circuitry and to generate an amplitude level indicator signal; and
control circuitry coupled to the bias current circuitry and configured to provide the multi-bit digital control signal to the plurality of selectable current drive circuits based upon the amplitude level indicator signal.

2. The digital crystal oscillator amplitude control circuitry of claim 1, wherein each of the plurality of selectable current drive circuits comprise a current drive transistor coupled to a switch circuit controlled by at least one bit of the multi-bit digital control signal.

3. The digital crystal oscillator amplitude control circuitry of claim 2, wherein each current drive transistor has its source and drain coupled between a supply node and a common output node, wherein each switch circuit is configured to selectably pass a voltage control signal to a gate of a current drive transistor, and wherein the common output node is coupled to provide the variable bias current to the crystal oscillator circuitry.

4. The digital crystal oscillator amplitude control circuitry of claim 3, further comprising current source circuitry coupled to a load circuit to provide the voltage control signal.

5. The digital crystal oscillator amplitude control circuitry of claim 2, wherein each current drive transistor has its source and drain coupled between a supply node and a switch circuit, wherein a voltage control signal is coupled to a gate of each drive transistor, wherein each switch circuit is configured to selectably couple the current drive transistor to a common output node, and wherein the common output node is coupled to provide the variable bias current to the crystal oscillator circuitry.

6. The digital crystal oscillator amplitude control circuitry of claim 5, further comprising current source circuitry coupled to a load circuit to provide the voltage control signal.

7. The digital crystal oscillator amplitude control circuitry of claim 1, wherein the amplitude detection circuitry comprises a peak detector and a comparator.

8. The digital crystal oscillator amplitude control circuitry of claim 1, wherein the control circuitry comprises clock generation circuitry coupled to receive the output signal from the crystal oscillator circuitry and to generate one or more clock signals.

9. The digital crystal oscillator amplitude control circuitry of claim 8, wherein the control circuitry further comprises logic circuitry configured to receive the amplitude level indicator signal, to receive the one or more clock signals from the clock generation circuitry, and to output the multi-bit digital control signal.

10. The digital crystal oscillator amplitude control circuitry of claim 9, wherein the logic circuitry comprises a finite state machine.

11. The digital crystal oscillator amplitude control circuitry of claim 1, wherein the plurality of selectable current drive circuits have a same weight.

12. The digital crystal oscillator amplitude control circuitry of claim 1, wherein at least two of the plurality of selectable current drive circuits have different weights.

13. The digital crystal oscillator amplitude control circuitry of claim 1, wherein the control circuitry is configured to set the multi-bit digital control signal to provide initially a maximum amplitude level for the output signal from the crystal oscillator circuitry.

14. A method for digitally controlling an amplitude level of an output signal from crystal oscillator circuitry, comprising:
determining an amplitude level for an output signal from crystal oscillator circuitry;
generating a multi-bit digital control signal based upon the amplitude level;
applying the multi-bit digital control signal to a plurality of selectable current drive circuits to provide a variable bias current to the crystal oscillator circuitry; and
repeating the determining, generating and applying steps to control the amplitude level of the output signal from the crystal oscillator circuitry.

15. The method of claim 14, wherein each of the plurality of selectable current drive circuits comprises a current drive transistor coupled to a switch circuit, and wherein the applying step comprises applying at least one bit of the multi-bit digital control signal to each switch circuit.

16. The method of claim 15, further utilizing the multi-bit digital control signal to selectably apply a voltage control signal to a gate of each current drive transistor to determine which of the plurality of selectable current drive circuits provide a current to a common output node, and utilizing the common output node to provide the variable bias current to the crystal oscillator circuitry.

17. The method of claim 15, further comprising utilizing the multi-bit digital control signal to selectably couple each drive transistor to a common output node, and utilizing the common output node to provide the variable bias current to the crystal oscillator circuitry.

18. The method of claim 1, further comprising generating one or more clock signals based upon the output signal from the crystal oscillator circuitry.

19. The method of claim 18, using logic circuitry to generate the multi-bit digital control signal based upon the amplitude level and using the one or more clock signals to control the logic circuitry.

20. The method of claim 14, further comprising setting the multi-bit digital control signal to provide initially a maximum amplitude level for the output signal from the crystal oscillator circuitry.
